(19) United States
(12) Patent Application Publication
(10) Pub. No.: US 2009/0322383 A1
(43) Pub. Date: Dec. 31, 2009

(54) SEMICONDUCTOR DEVICE, SIGNAL TRANSMITTER, AND SIGNAL TRANSMISSION METHOD

(75) Inventors: Muneo Fukaishi, Tokyo (JP); Yoshihiro Nakagawa, Tokyo (JP); Tadahiro Kuroda, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC Corporation, Minato-ku Tokyo (JP)

(21) Appl. No.: 12/304,397

(22) PCT Filed: Jun. 1, 2007
(86) PCT No.: PCT/JP2007/061176

§ 371 Date: Dec. 11, 2008

(30) Foreign Application Priority Data
Jun. 12, 2006 (JP) 2006 162296

(51) Int. Cl. H03K 3/00

(52) U.S. Cl. 327/110

(57) ABSTRACT

A semiconductor device is provided with a plurality of semiconductor chips and at least one transmission coil (108) for transmitting signals by using inductor coupling between the semiconductor chips. A plurality of transmission coils are connected in series.

### TECHNICAL FIELD

The present invention relates to a semiconductor device, a signal transmitter, and a signal transmission method for transmitting data using an inductive coupling.

### BACKGROUND ART

Semiconductor integrated circuits have their integration density increased as the transistor devices which make up the semiconductor integrated circuits have been reduced in size, and one-chip semiconductor integrated devices have begun to incorporate many types of functions. Semiconductor memory devices have been having growing memory capacities regardless of the types of memory circuits including DRAM (dynamic random access memory) and SRAM (static random access memory), as the transistor devices have been reduced in size.

In recent years, however, since firstly, semiconductor chips are required to have more multifunctional capability and greater capacity than the increased functionality and capacity provided by smaller-size transistor devices and secondly, there is a limitation on efforts to reduce the size of transistor devices, there has been a demand for new technologies for further increasing the integration density and, as a result, achieving more multifunctional capability and greater capacity. As one of such technologies, a stacked semiconductor device having a plurality of stacked semiconductor chips, or a so-called three-dimensional semiconductor, has been proposed.

For example, as a means for realizing a large-scale integrated circuit by stacking semiconductor chips without changing the chip area, a memory circuit that is integrated on another chip stacked on a semiconductor integrated circuit proper is disclosed in JP-A No. 04-196263. Similarly, as a means for realizing a large-scale integrated circuit without changing the chip area, a multi-layer memory structure comprising memory cell arrays in multiple layers for a larger capacity is disclosed in JP-A No. 2002-26283.

A plurality of semiconductor chips arranged in multiple layers need wires between the chips in addition to existing interconnects on the chips. The wires between the chips are often in the form of connections produced by wire bonding. Since wire bonding is a technology for interconnecting pads on the surfaces of the chips, wire bonding as applied to stacked semiconductors suffer at least three problems.

The first problem is that the number of wires that can be used is limited because each pad requires a certain pad area of 100 μm square, for example. The second problem is that the number of wires that can be used is also limited because the pads on the surfaces of the semiconductor chips need to be disposed outside of the stacked chips so that the pads can be connected from outside of the chips. The third problem is that, as with the second problem, since the pads on the surfaces of the semiconductor chips need to be disposed outside of the stacked chips so that the pads can be connected from outside of the chips, if semiconductor chips of the same shape are stacked, the pads for bonding wires cannot be taken out.

Particularly, the first and second problems, i.e., the limited number of wires that can be used, are responsible for a limitation on the performance improvements of multifunctional capability and greater capacity achieved by the stacked structure in view of the fact that the amount of data transmitted between the chips increases due to the performance improvements of multifunctional capability and greater capacity achieved by the stacked chips. Generally, two data transmission technologies have been developed as solutions to the above problems.

The first technology is concerned with through interconnects extending through semiconductor chips. According to a report by Takahashi et al. (K. Takahashi, et al., “Current Status of Research and Development for Three-Dimensional Chip Stack Technology”, Japanese Journal of Applied Physics, Vol. 40 (2001) 3032-3037 Part 1, No. 4B, 30 Apr. 2001), a silicon chip is thinned down to 50 μm, a hole of 10 μm square is opened in the silicon chip, and the hole is filled with metal to produce a through interconnect between chips. The through interconnect technology allows inter-chip interconnects to be arranged two-dimensionally on chip surfaces, and makes it possible to produce several hundred inter-chip interconnects. In addition, as inter-chip interconnects extend through chips, it is possible to stack semiconductor chips of the same shape.

The second technology employs a noncontact interface technology for data transmission between a plurality of semiconductor chips. The noncontact interface technology is roughly classified into a capacitive coupling transmission technology which uses a capacitance and an inductive coupling transmission technology which uses inductors. A report by Kanda, et al. (K. Kanda, et al., “1.27 Gb/s/pin 3 mW/pin Wireless Superconnect (WSC) Interface Scheme”, International Solid-State Circuits Conference Dig Tech Papers, pp. 186-187, February 2003) shows a scheme and a circuit wherein pads are mounted at intervals of 40 μm on semiconductor chips, and a plurality of chips are stacked face to face, providing a capacitive coupling between the pads for transmitting data therethrough. A report by Mizoguchi, et al. (D. Mizoguchi, et al., “A 1.2 Gb/s/pin Wireless Superconnect Based on Inductive Inter-chip Signaling (IIS)”, International Solid-State Circuits Conference, 2004), shows a scheme and a circuit wherein coils in the form of spiral inductors are mounted in semiconductor interconnect regions at intervals of 100 μm on semiconductor chips, and a plurality of chips are stacked face to back, providing a inductive coupling for transmitting data therethrough.

If a plurality of semiconductor chips are stacked based on the technologies of the through interconnects, the capacitive coupling, and the inductive coupling, then a greater data transmission capability between chips is accomplished than if chips are stacked based on the wire bonding technology. Those technologies make it possible to stack not only memory circuits, shown above by way of example, but also logic circuits and analog circuits for more multi-functional capability in addition to greater memory capacity.

However, the through interconnect technology tends to make the semiconductor fabrication process complex because of the step of forming holes referred to as through vias in the semiconductor substrates of semiconductor chips and filling the through vias with a conductive material such as metal to form interconnects for connecting the face and back of the semiconductor chips for data transmission, and the step of providing an insulating material for insulating the through interconnects and the semiconductor substrates from each other. In addition, the through interconnect technology is also problematic in that the cost of semiconductor fabrication becomes high and the period of semiconductor fabrication increases.

According to the capacitive coupling technology, the stacked chips need to be oriented face to face because the pads on the surfaces of the chips are held in confronting relationship to provide a capacitive coupling. As a result, the number of stacked chips is limited to two, and it is difficult to stack three or more chips, thereby imposing a limitation on efforts to achieve more multifunctional capability and greater capacity.

Unlike the capacitive coupling technology, the process of stacking chips using an inductive coupling makes it possible to stack three or more chips because a semiconductor substrate inserted in an inductive coupling allows a magnetic field induced between a plurality of coils to pass through the semiconductor substrate. Consequently, the noncontact interface technology based on the inductive coupling, when applied as a technology for stacking three or more chips, is highly likely to contribute to making semiconductor devices more multifunctional and larger in capacity.

The noncontact interface technology based on the inductive coupling will briefly be described below. FIG. 1 is a block diagram showing a configurational example of a relevant transmitting section and a relevant receiving section for transmitting and receiving data between chips. It is assumed that 1-bit data are to be sent from one chip to another chip and that the polarity of data represented by a signal voltage is “0” if the signal voltage is a grounded potential and “1” if the signal voltage is a predetermined voltage different from the grounded potential.

As shown in FIG. 1, a transmitting section on chip 1801 for transmitting data comprises transmission coil 1805 and variable-current-direction current supplies 1803, 1804 which are capable of changing the direction of a current flowing through transmission coil 1805, which is disposed between variable-current-direction current supplies 1803, 1804. Variable-current-direction current supplies 1803, 1804 change the direction of the current depending on transmission data input to data input terminal 1802. In FIG. 1, the direction of the current is assumed to be positive when the current flows from the left to right through transmission coil 1805, and negative when the current flows back. A receiver on chip 1806 for receiving data comprises reception coil 1807 and receiver 1808 connected parallel to reception coil 1807. Receiver 1808 reads a current change induced across reception coil 1807. Chips 1801, 1806 are stacked together such that transmission coil 1805 and reception coil 1807 are essentially superposed one on the other in a direction perpendicular to the chip surfaces.

When the polarity of the transmission data input to data input terminal 1802 changes from “0” to “1”, variable-current-direction current supplies 1803,1804 supply a current in the positive direction to transmission coil 1805 in timed relation to the polarity change. When the direction of the current flowing through transmission coil 1805 changes, a magnetic field is generated in transmission coil 1805 due to an electromagnetic induction, inducing current across reception coil 1807. Receiver 1808 reads a current change induced across reception coil 1807. When the polarity of the transmission data input to data input terminal 1802 changes from “1” to “0”, the direction of the current flowing through transmission coil 1805 also changes, inducing current across reception coil 1807, and receiver 1808 reads a current change induced across reception coil 1807. The magnetic fields generated in transmission coil 1805 when the polarity of the transmission data changes from “0” to “1” and when the polarity of the transmission data changes from “1” to “0” have different directions, and the corresponding current changes read by receiver 1808 are different from each other. Therefore, reception data output from data output terminal 1809 correspond to the polarity of the transmission data. Accordingly, data can be transmitted between the chips without the need for interconnects for transmission data between the stacked chips.

FIG. 2 is a circuit diagram showing a configurational example of a relevant transmitting section for transmitting a plurality of data. As shown in FIG. 2, the transmitting section comprises a plurality of transmission circuits 1951 through 1953 stacked together for simultaneously transmitting multibit data. Though only three transmission circuits are shown, the number of transmission circuits is not limited to three, but may be in the range from 1 to n (n is an integer of 2 or greater). Since the multibit data are handled, the number of transmission circuits is represented by n.

Transmission circuit 1951 comprises transmission coil 1911 for transmitting transmission data Tdata1 and MOS switches 1907 through 1910 for controlling the direction of a current flowing through transmission coil 1911 depending on transmission data Tdata1. Other transmission circuits 1912, 1913 are identical in configuration to transmission circuit 1951 and will not be described in detail below. Pulse generator 1915 for generating a pulse signal for determining the transmission timing for data is connected to transmission circuits 1951 through 1953.

FIG. 3 is a circuit diagram showing a configurational example of a relevant receiving section. The receiving section shown in FIG. 3 is provided on a data reception side. The illustrated circuit serves to receive one data. Since the configurational details are disclosed in the report by Mizoguchi, et al., they will not be described below, but operation of the receiver will briefly be described below. Reference intermediate voltage 2005 is applied to a point between two resistors that are connected parallel to reception coil 2001. When an inductive electromotive force is generated across reception coil 2001 at the timing of reception clock 2002, a voltage change is detected, and the polarity of the data is output as reception data 2003 and inverted data of reception data 2003 are also output as inverted reception data 2004.

### DISCLOSURE OF THE INVENTION

The noncontact interface based on the inductive coupling makes it easy to produce a stacked semiconductor device having a plurality of stacked semiconductor chips, or a so-called three-dimensional semiconductor. However, according to the relevant data transmission scheme, if multibit data are to be transmitted, then a plurality of transmission circuits, each for transmitting a bit, need to be arranged for handling respective transmission data Tdata1 through Tdatan.

According to the above scheme, if data of polarity 1 are to be transmitted as transmission data Tdata1, MOS switches 1907 through 1910 shown in FIG. 2 are controlled depending on the transmission data to supply a current from power supply 1916 to flow through transmission coil 1911 to ground 1917. In other words, the current that flows through transmission coil 1911 for transmitting transmission data Tdata1 with data number 1 flows only through transmission coil 1911. Each time data are transmitted, the current from the power supply flows through one transmission coil to ground, and the current flow is terminated. The above operation is the same for all the other bits. For simultaneously transmitting many bits, currents depending on the number of transmission bits are caused to flow through as many transmission coils as the number of transmission bits. Each time data are transmitted, the current from the power supply flows through one transmission coil to ground, and the current flow is terminated. As a consequence, the number of transmission currents increases in proportion to the number of transmission bits.

The present invention has been made in an effort to solve the problems of the above technologies. It is an object of the present invention to provide a semiconductor device, a signal transmitter, and a signal transmission method for reducing currents to be consumed and reducing electric power consumed by chips for transmitting multibit data using an inductive coupling.

To achieve the above object, a semiconductor device according to the present invention includes a plurality of semiconductor chips and at least one transmission coil for transmitting a signal between the semiconductor chips using an inductive coupling, wherein the transmission coil comprises a plurality of transmission coils connected in series with each other.

According to the present invention, since a current which flows for transmitting the signal is used via the transmission coils that are connected in series with each other, the semiconductor device consumes less electric power than if currents are supplied to the respective transmission coils.

According to the present invention, the semiconductor device does not invite an increase in the transmission power which is proportional to the number of transmission bits, as observed when multibit data are transmitted according to the background art. The current consumed when multibit data are transmitted can be reduced, and the power consumption by the chips can be reduced.

### BRIEF DESCRIPTION OF THE DRAWINGS

FIG. 1 is a block diagram showing a configurational example of a relevant transmitting section and a relevant receiving section for transmitting and receiving data between chips;

FIG. 2 is a circuit diagram showing a configurational example of a relevant transmitting section;

FIG. 3 is a circuit diagram showing a configurational example of a relevant receiving section;

FIG. 4 is a block diagram of a transmitting section of a semiconductor device according to a first exemplary embodiment;

FIG. 5 is a circuit diagram showing a configurational example of transmitters shown in FIG. 4;

FIG. 6 is a timing chart of the transmitters shown in FIG. 5;

FIG. 7 is a block diagram showing a configurational example of a pulse generator shown in FIG. 5;

FIG. 8 is a timing chart of the pulse generator shown in FIG. 7;

FIG. 9 is a block diagram showing a configurational example of a variable delay unit shown in FIG. 7;

FIG. 10 is a circuit diagram showing a configurational example of a variable delay element shown in FIG. 9;

FIG. 11 is a circuit diagram showing another configurational example of the variable delay element shown in FIG. 9;

FIG. 12 is a block diagram of a transmitting section of a semiconductor device according to a second exemplary embodiment;

FIG. 13 is a circuit diagram showing a configurational example of the transmitting section shown in FIG. 12;

FIG. 14 is a timing chart of the transmitting section shown in FIG. 13;

FIG. 15 is a circuit diagram and a power comparison table which are illustrative of the manner in which the transmitting section shown in FIG. 13 operates;

FIG. 16 is a graph showing power reducing effects according to the first and second exemplary embodiments;

FIG. 17A is a graph showing transmission voltages for data transmission;

FIG. 17B is a graph showing transmission currents according to the first exemplary embodiment at a constant transmission voltage;

FIG. 17C is a graph showing transmission currents according to the second exemplary embodiment at a constant transmission voltage;

FIG. 18 is a graph showing the relationship between the transconductance and the transmission frequency according to the first and second exemplary embodiments;

FIG. 19A is a graph showing the results of characteristics of transmission currents according to the second exemplary embodiment;

FIG. 19B is a graph showing the results of characteristics of reception voltages according to the second exemplary embodiment; and

FIG. 20 is a graph showing the relationship between the data skew and the number of coils according to the second exemplary embodiment.

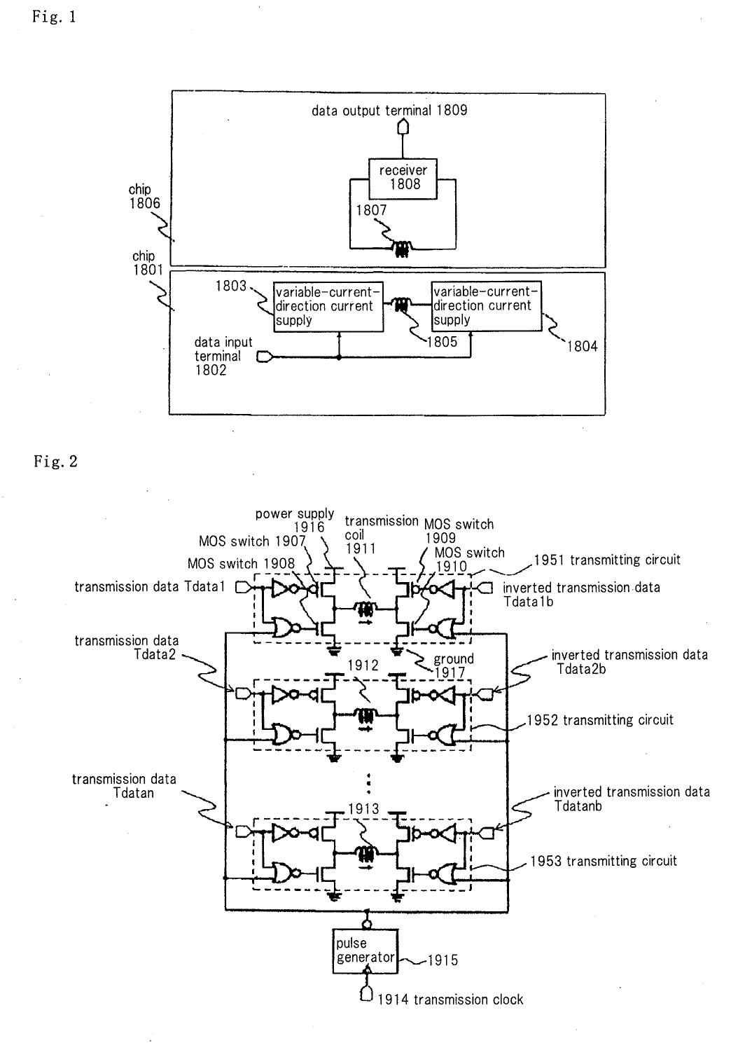

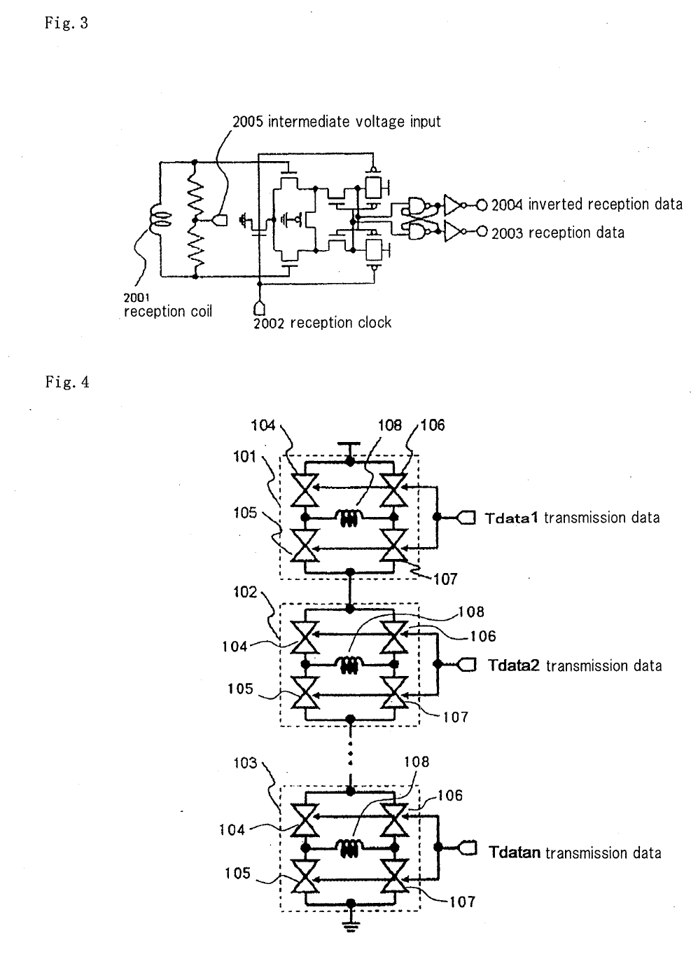

### DESCRIPTION OF REFERENCE CHARACTERS

101, 102, 103 transmitter
108 transmission coil
10 104, 105, 106, 107 switch

### BEST MODE FOR CARRYING OUT THE INVENTION

A semiconductor device according to the present invention is characterized in that a plurality of transmission coils for signal transmission are connected in series with each other. Exemplary embodiments of semiconductor devices according to the present invention will be described below. Configurations and methods for data transmission which are relevant to the present invention will be described below, and those configurational details which are identical to those of the semiconductor devices described above will not be described in detail below.

### 1st Exemplary Embodiment

A semiconductor device according to the present exemplary embodiment will be described below. FIG. 4 is a block diagram of a transmitting section of the semiconductor device according to the present exemplary embodiment.

The transmitting section of the semiconductor device according to the present exemplary embodiment includes a plurality of transmitters 101 through 103. While the transmitters are distinguished by reference numerals 101 through 103, the number of transmitters that are employed is not limited to three, but may be in the range from 1 to n (n is an integer of 2 or greater). As shown in FIG. 4, transmitters 101 through 103 are connected together in a row between a single power supply terminal and a single ground terminal.

Configurational details of transmitters 101 through 103 will be described below. Since transmitters 101 through 103 are identical in configuration to each other, transmitter 101 will mainly be described below as typical of these transmitters.

Transmitter 101 comprises transmission coil 108 for transmitting transmission data Tdata1 to an external circuit, switches 104, 106 for supplying a power supply voltage to one of the terminals of transmission coil 108, and switches 105, 107 for connecting the other of the terminals of transmission coil 108 to ground. Switches 104, 106 are connected parallel to the power supply terminal. Switches 105, 107 are connected parallel to the power supply terminal of transmitter 102. Transmission coil 108 is connected between the junction between switches 104, 105 and the junction between switches 106, 107. Switches 104 through 107 are supplied with transmission data Tdata1.

Operation of transmitter 101 will briefly be described below. When the polarity of transmission data Tdata1 is 1, switches 104, 107 are turned on and switches 106, 105 are turned off, allowing a current to flow in the positive direction from the power supply terminal through transmission coil 108. Conversely, when the polarity of transmission data Tdata1 is 0, switches 104, 107 are turned off and switches 106, 105 are turned on, allowing a current to flow in the negative direction from the power supply terminal through transmission coil 108. When a current flows through the transmission coil 108, the transmission coil 108 transmits data corresponding to the direction of the current to the external circuit.

As described above, the transmitters of the transmitting section determine the direction of the current flowing through transmission coil 108 depending on transmission data Tdata1 through Tdatan. Irrespectively of whether the direction of the current flowing through transmission coil 108 is positive or negative, the current flowing through transmission coil 108 is input to the transmitter that is connected to ground.

Operation of the transmitting section shown in FIG. 4 will be described below. When transmission data Tdata1 through Tdatan are input to the transmitting section, transmitter 101 transmits transmission data Tdata1 from transmitter 108 to the external circuit. The current flowing through transmission coil 108 is delivered to the power supply terminal of next transmitter 102. As with transmitter 101, transmitter 102 controls the direction of the current flowing through transmission coil 108 depending on transmission data Tdata2 using four switches 104 through 107, and transmits transmission data Tdata2 through transmission coil 108. The current flowing through transmission coil 108 of transmitter 102 is delivered to the power supply terminal of the next transmitter. In this manner, the current flowing through transmission coil 108 is delivered successively from the transmitter on the power supply side to the transmitter on the ground side until the current passes through transmission coil 108 of transmitter 103 on the final stage and then flows to ground, whereupon the consumption of the current is finished. The transmitters of the transmitting section transmit the data from transmission coils 108 depending on transmission data Tdata1 through Tdatan.

Since the transmitters are connected together in a row, the transmission coils are connected in series with each other, and the current used for data transmission by the transmitter in a preceding stage is used again by the transmitter in a next stage, the consumption of the current for transmitting a plurality of data can be reduced.

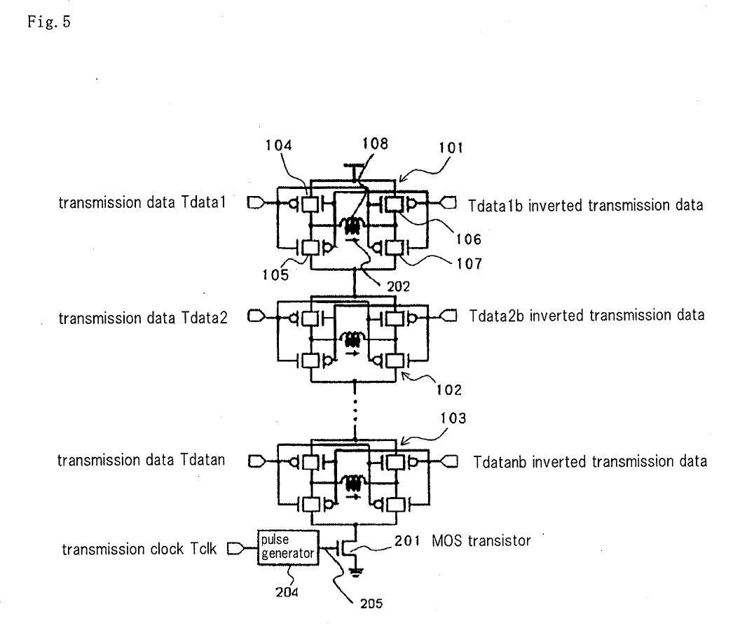

An example of a circuit of transmitter 110 shown in FIG. 4 will be described below. FIG. 5 is a circuit diagram showing a configurational example of the transmitters shown in FIG. 4.

As shown in FIG. 5, each of switches 104 through 107 of transmitters 101 through 103 comprises NMOS and PMOS transistors connected parallel to each other. The transmitting section includes pulse generator 204 for controlling the timing of data transmission. MOS transistor 201 is connected between transmitter 103 in the final stage and the ground terminal, and pulse generator 204 has an output terminal connected to the gate of MOS transistor 201. Pulse generator 204 turns on and off MOS transistor 201 based on transmission block Tclk.

The gates of the PMOS transistors of switches 104, 107 and the NMOS transistors of switches 105, 106 are supplied with transmission data Tdata1. The gates of the NMOS transistors of switches 104, 107 and the PMOS transistors of switches 105, 106 are supplied with inverted transmission data Tdata1b which are an inverted signal of transmission data Tdata1.

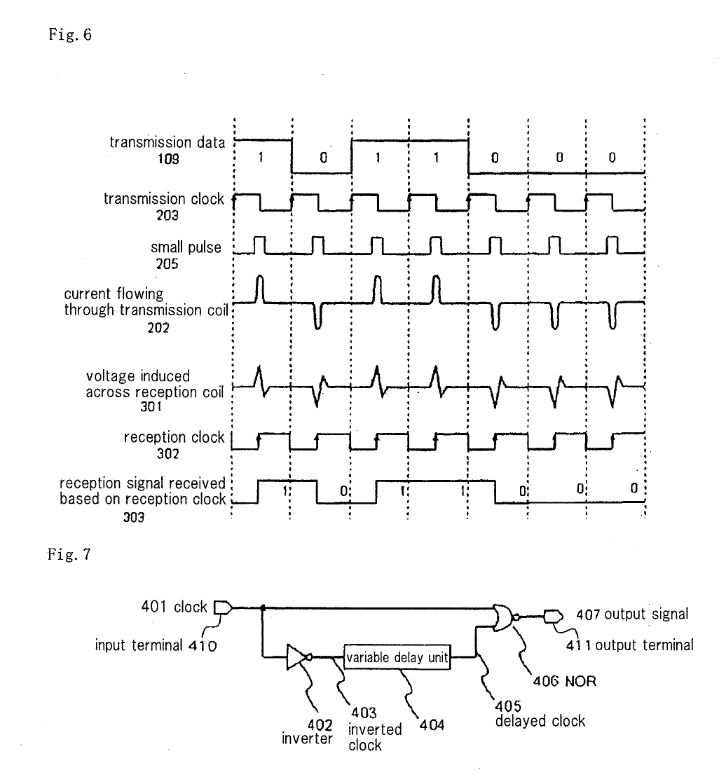

FIG. 6 is a timing chart of the transmitters shown in FIG. 5. Specifically, transmitter 101 is illustrated, and transmission data Tdata1 is denoted by reference numeral 109.

As shown in FIG. 6, pulse generator 204 generates small pulses 205 based on transmission clock 203. When the polarity of transmission data 109 is 1, current 202 flows through transmission coil 108 in timed relation to small pulses 205. Voltage 301 is induced across the reception coil on the semiconductor chip for receiving the data, and converted into data at the timing of reception clock 302, whereupon the polarity of reception signal 303 becomes 1. Similarly, when the polarity of transmission data 109 is 0, the polarity of reception signal 303 becomes 0 on the chip for receiving the data.

With the above configuration, the current used to transmit a plurality of data is constant regardless of the number of transmitters connected together in a row. Therefore, a current reducing effect is expected depending on the number of transmitters connected together in a row.

Configurational details of pulse generator 204 shown in FIG. 5 will be described below.

FIG. 7 is a block diagram showing a configurational example of the pulse generator shown in FIG. 5. As shown in FIG. 7, a path extending from input terminal 410 is branched into two paths, one of which is connected to an input of NOR 406 as a logic circuit. The other of the branched paths is connected through inverter 402 as a logic circuit and variable delay unit 404 to an input of NOR 406. NOR 406 has an output connected to output terminal 411. The pulse generator divides input clock 401 into two signals, one of which is delayed by variable delay unit 404, and inputs the delayed signal and clock 401 to NOR 406, which generates output signal 407 having a small pulse waveform.

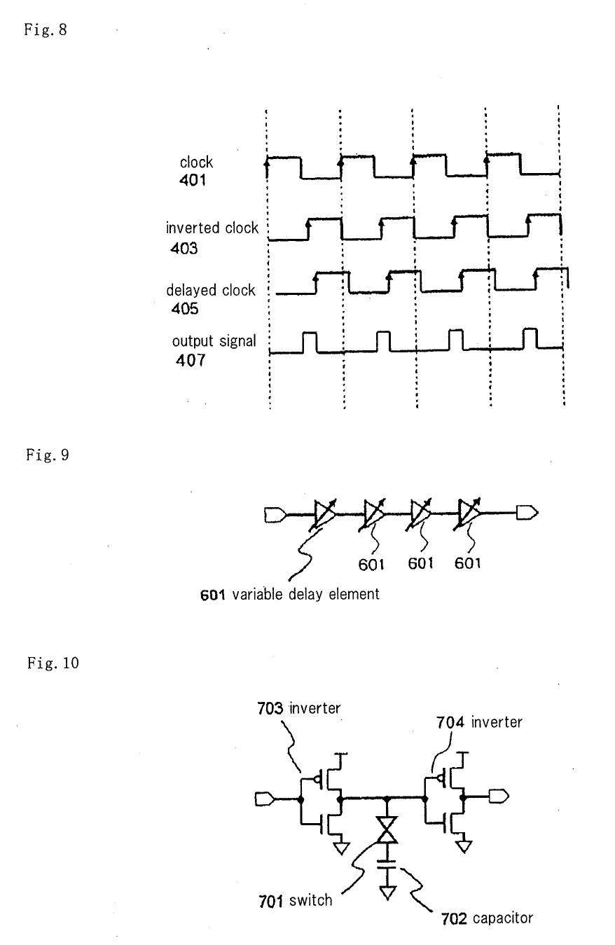

FIG. 8 is a timing chart of the pulse generator shown in FIG. 7. When clock 401 passes through inverter 402, it is converted into inverted clock 403. When inverted clock 403 passes through variable delay unit 404, it is converted into delayed clock 405 which has a time delay as shown in FIG. 8 with respect to inverted clock 403. When NOR 406 is supplied with clock 401 and delayed clock 405, it outputs output signal 407 shown in FIG. 8. Output signal 407 corresponds to small pulses 205. The delay time of delayed clock 405 with respect to clock 701 represents the pulse duration of the small pulses. Since the pulse duration is set by the deviation between the two clocks, it is one-half of the clock period at maximum.

Configurational details of variable delay unit 404 shown in FIG. 7 will be described below. FIG. 9 is a block diagram showing a configurational example of the variable delay unit shown in FIG. 7. Variable delay unit 404 comprises a plurality of variable delay elements 601. As shown in FIG. 9, variable delay elements 601 are connected in series with each other.

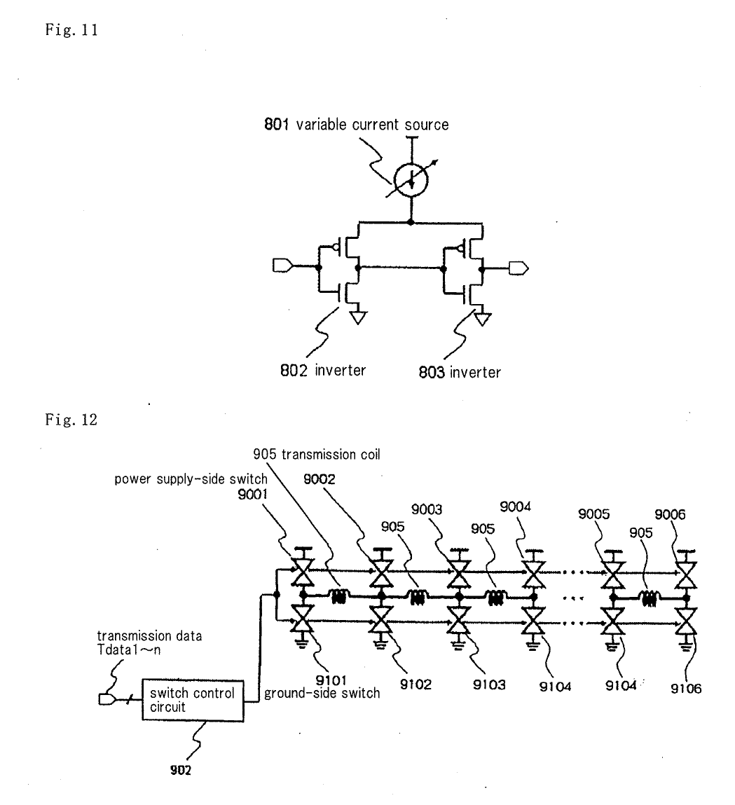

FIGS. 10 and 11 are circuit diagrams showing configurational examples of the variable delay element shown in FIG. 9. The variable delay element shown in FIG. 10 comprises two inverters 703, 704, capacitor 702, and switch 701 for connecting capacitor 702 to and disconnecting capacitor 702 from the junction between inverters 703, 704. When switch 701 is turned on or off, capacitor 702 is connected to or disconnected from the output of inverter 703 in the preceding stage, thereby changing the load on inverter 703 to change the delay time of the clock. The variable delay element may have a plurality of capacitors 702 or a number of capacitors 702 having different capacitance values, and a plurality of switch elements 701 depending on the number of capacitors 702, and switches 701 may be controlled to set a plurality of types of delay times.

The variable delay element shown in FIG. 11 comprises two inverters 802, 803 and variable current source 801. Inverters 802, 803 have respective sources connected to variable current source 801. When the amount of current flowing from variable current source 801 is controlled, currents that inverters 802, 803 can pass are controlled for thereby controlling the delay times of inverters 802, 803. If variable current source 801 has a plurality of types of the variable amount of current, then the variable delay element can set a plurality of types of delay times.

### 2nd Exemplary Embodiment

A semiconductor device according to the present exemplary embodiment will be described below. FIG. 12 is a block diagram of a transmitting section of the semiconductor device according to the present exemplary embodiment.

As shown in FIG. 12, the transmitting section of the semiconductor device according to the present exemplary embodiment comprises a plurality of transmission coils 905 connected in series with each other, power supply-side switches 9001 through 9006 each serving as a selector switch for connecting or disconnecting the junction between two adjacent transmission coils to or from a power supply, and ground-side switches 9101 through 9106 each serving as a selector switch for connecting or disconnecting the junction to or from ground. The number of the power supply-side switches and the number of the ground-side switches are equal to each other. If the number of transmission coils 905 is in the range from 1 to n (n is an integer of 2 or greater), then the number of the power supply-side switches and the number of the ground-side switches are represented by (n+1) each.

The transmitting section also includes switch control circuit 902 for supply transmission data Tdata1 through Tdatan to power supply-side switches 9001 through 9006 and ground-side switches 9101 through 9106. Switch control circuit 902 is connected to power supply-side switches 9001 through 9006 and ground-side switches 9101 through 9106. These switches are controlled by switch control circuit 902 depending on transmission data Tdata1 through Tdatan.

FIG. 13 is a circuit diagram showing a configurational example of the transmitting section shown in FIG. 12. As shown in FIG. 13, PMOS transistor (hereinafter simply referred to as “PMOS”) 1010 is provided as power supply-side switch 9001. NMOS transistor (hereinafter simply referred to as “NMOS”) 1015 is provided as ground-side switch 9101. PMOS 1011 is connected as a power supply-side switch and NMOS 1016 is connected as a ground-side switch to the junction between transmission coil 1020 and transmission coil 1021. PMOS 1012 on the power supply side and NMOS 1017 on the ground side are connected to the terminal of transmission coil 1021 which is remote from transmission coil 1020.

PMOS 1013 on the power supply side and NMOS 1018 on the ground side are connected to the junction between transmission coil 1022 in a final stage and the transmission coil in a preceding stage. PMOS 1014 on the power supply side and NMOS 1019 on the ground side are connected to the other terminal of transmission coil 1022. Pulse generator 1008 for generating small pulses from transmission clock Tclk is connected to each of the ground-side switches.

Inverter 1051 has an output terminal connected to the gate of PMOS 1010. Transmission data Tdata1 are input to the gate through inverter 1051. NOR 1052 inputs an output signal thereof to NMOS 1015. NOR 1052 is supplied with a signal produced by inverter 1053 from inverted transmission data Tdata1 b and the small pulse signal from pulse generator 1008.

The gate of PMOS 1011 is connected to the output terminal of NAND 1054 as a logic circuit. NAND 1054 is supplied with transmission data Tdata2 and a signal produced by inverter 1055 from transmission data Tdata1. The gate of NMOS 1016 is connected to the output terminal of NOR 1056. NOR 1056 is supplied with the small pulse signal from pulse generator 1008 and an output signal from NAND 1057. NAND 1057 is supplied with inverted transmission data Tdata2b and a signal produced by inverter 1058 from inverted transmission data Tdata1b.

The gate of PMOS 1014 is supplied with transmission data Tdatan. The gate of NMOS 1019 is supplied with an output signal from NOR 1058. NOR 1058 is supplied with the small pulse signal from pulse generator 1008 and inverted transmission data Tdatanb.

Of n transmission coils 1020 through 1022, the kth (k is an integer ranging from 1 to n) transmission coil transmits either transmission data Tdatak or inverted transmission data Tdatakb to an external circuit. A current flowing through the kth transmission coil has its direction variable depending on the small pulses generated by pulse generator 1008 depending on transmission clock Tclk, transmission data Tdatak, and inverted transmission data Tdatakb. Operation of the transmitting section shown in FIG. 13 will be described below with reference to a timing chart.

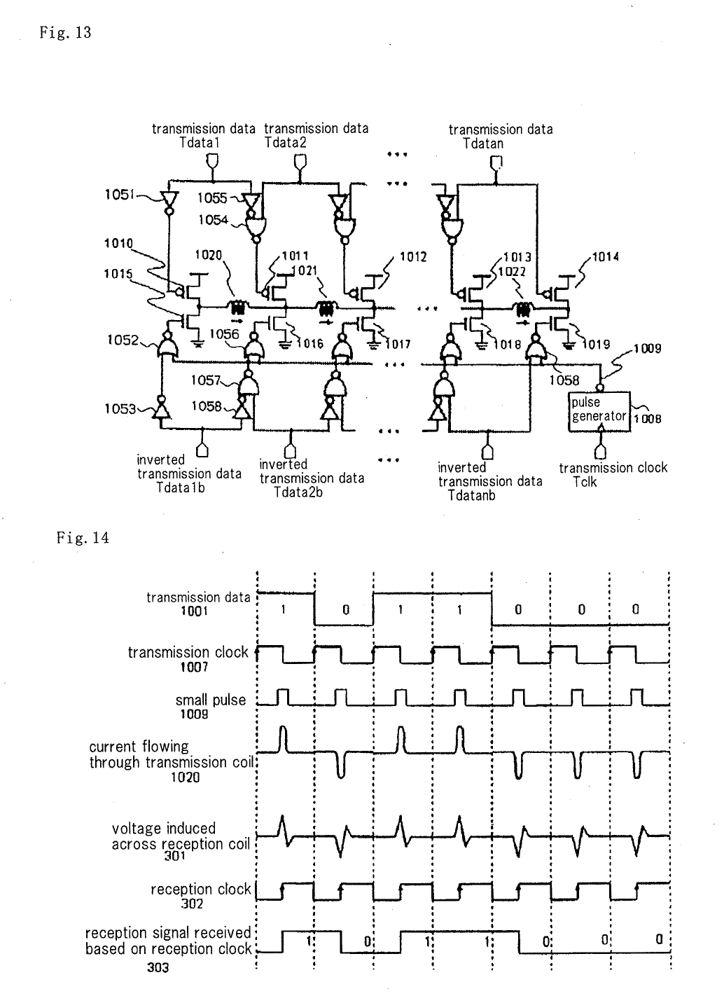

FIG. 14 is a timing chart of the transmitting section shown in FIG. 13. In FIG. 14, transmission data Tdata1 are denoted by reference numeral 1001 and transmission clock Tclk by reference numeral 1007. As shown in FIG. 14, pulse generator 1008 generates small pulses 1009 based on transmission clock 1007. When the polarity of transmission data 1001 is 1, PMOS 1010 is turned on, NMOS 1015 is turned off, and either one of NMOS 1016 and NMOSs in subsequent stages is turned on, causing current 1020 to flow through transmission coil 1020. Voltage 301 is induced across the reception coil on the semiconductor chip for receiving the data, and converted into data at the timing of reception clock 302, whereupon the polarity of reception signal 303 becomes 1. Similarly, when the polarity of transmission data 1001 is 0, the polarity of reception signal 303 becomes 0 on the chip for receiving the data.

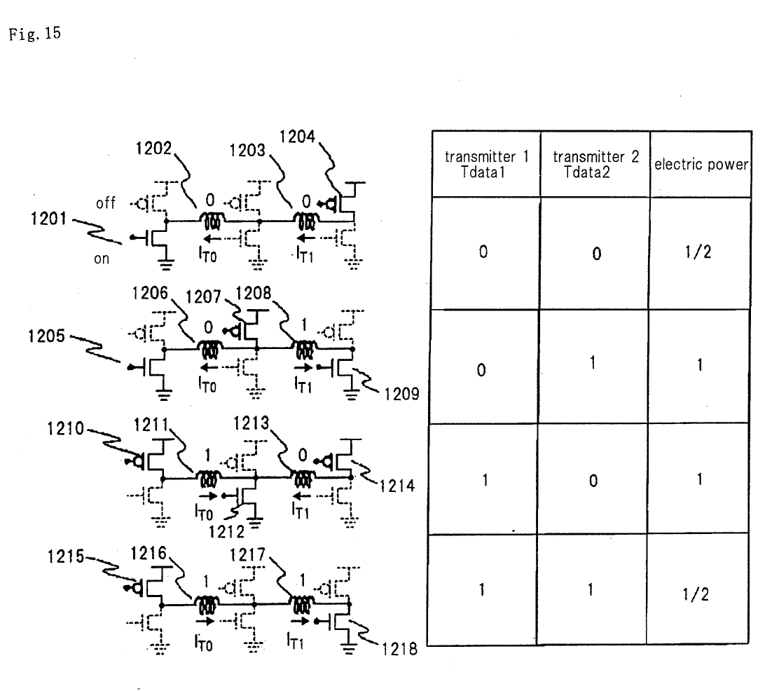

Operation of the transmitting section shown in FIG. 13 in the case where two transmission coils are employed will be described below. FIG. 15 is a circuit diagram and a power comparison table which are illustrative of the manner in which the transmitting section shown in FIG. 13 operates. In the circuit diagram shown in FIG. 15, the MOS transistor switches that are turned on are indicated by the solid lines, and the MOS transistor switches that are turned off are indicated by the broken lines. Transmission coils for transmitting transmission data Tdata1 are denoted by reference numerals 1202,1206, 1211, 1216, and transmission coils for transmitting transmission data Tdata2 are denoted by reference numerals 1203, 1208, 1213, 1217. FIG. 15 shows four cases of operation for transmission data Tdata1 and transmission data Tdata2.

In the first case, the polarity of both transmission data Tdata1 and transmission data Tdata2 is 0. In this case, NMOS 1201 and PMOS 1204 are turned on, and the other MOS switches are turned off. As a result, the current flowing from the power supply through PMOS 1204 flows through transmission coils 1203, 1202 and NMOS 1201 to ground. If the polarity of both transmission data Tdata1 and transmission data Tdata2 is 1 in the fourth case, then PMOS 1215 and NMOS 1218 are turned on, and the other MOS switches are turned off, causing a current to flow in the positive direction through transmission coils 1216, 1217.

In the second case, the polarity of transmission data Tdata1 is 0 and the polarity of transmission data Tdata2 is 1. In this case, two NMOSs 1205, 1209 and PMOS 1207 are turned on, and the other MOS switches are turned off. Now, a current flows in the negative direction through transmission coil 1206, and a current flows in the positive direction through transmission coil 1208. In the third case, the polarity of transmission data Tdata1 is 1 and the polarity of transmission data Tdata2 is 0. In this case, two NMOSs 1210, 1214 and PMOS 1212 are turned on, and the other MOS switches are turned off, so that a current flows in the positive direction through transmission coil 1211, and a current flows in the negative direction through transmission coil 1213.

The table shown in FIG. 15 illustrates how currents flow through the transmission coils depending on the data transmitted by the transmitters, with respect to transmitter 1 corresponding to transmission coils 1202, 1206, 1211, 1216 and transmitter 2 corresponding to transmission coils 1203, 1208, 1213, 1217.

When the polarity of both transmission data Tdata1 and transmission data Tdata2 is 0 or the polarity of these data is 1, the current flowing through two transmission coils 1202, 1203 connected together in a row or the current flowing through two transmission coils 1216, 1217 connected together in a row is considered to be equal to the current flowing through one transmission coil according to the background art. Therefore, the electric power consumed by one transmitter is one-half of the electric power consumed according to the background art. When the polarity of transmission data Tdata1 is 0 and the polarity of transmission data Tdata2 is 1 or when the polarity of transmission data Tdata1 is 1 and the polarity of transmission data Tdata2 is 0, the current flowing through the two transmission coils is not equal to the current flowing through one transmission coil according to the background art, but is estimated as a current flowing through each of two transmission coils, and hence a total of the currents flowing through the two transmission coils. Accordingly, the electric power is equal to the electric power consumed by transmission coils that are not connected together in a row according to the background art. It can be understood from these results that the electric power consumption can be smaller than the background art depending on the pattern of a plurality of transmission data.

According to the present exemplary embodiment, a current reducing effect varies depending on the pattern of data to be transmitted and the number of transmission coils connected together in a row. Even though the transmission coils are connected in series with each other, the currents flowing through adjacent ones of the transmission coils have different directions, making it possible to transmit data having different polarities.

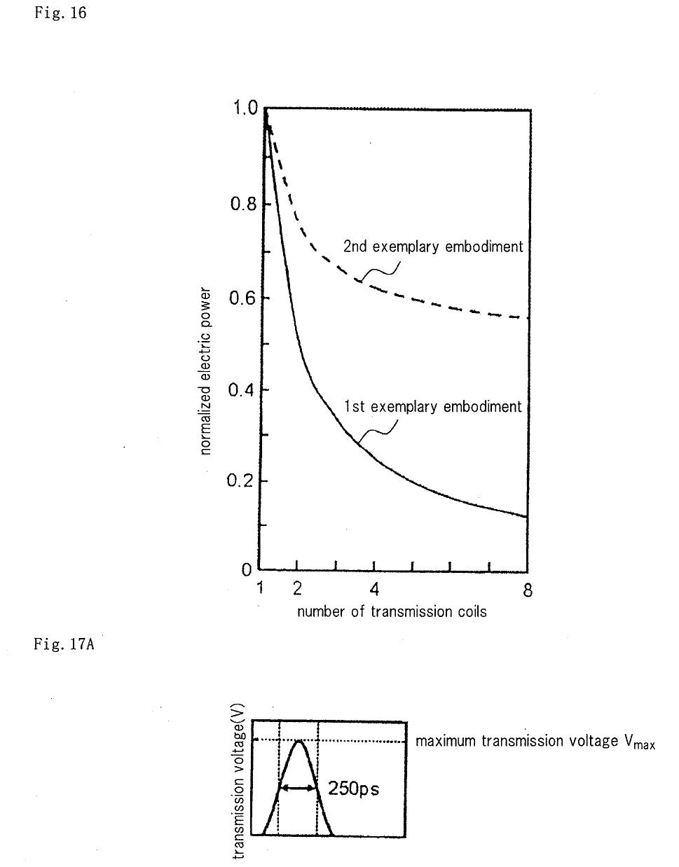

Power reducing effects of the transmitting sections of the semiconductor devices according to the first and second exemplary embodiments will be described below. FIG. 16 is a graph showing power reducing effects according to the first and second exemplary embodiments, showing the relationship between the power reducing effects according to the embodiments and transmission inductors connected together in a row.

The electric power is estimated using a random data pattern, and the values normalized against an electric power level of 1 obtained by a process wherein inductors are not connected together in a row according to the background art are plotted in the graph. According to the first exemplary embodiment, the electric power is reduced in inverse proportion to the number of transmission coils connected together in a row. According to the second exemplary embodiment, since the power reducing effect depends on the data pattern, the electric power is reduced by about 40% compared with the background art.

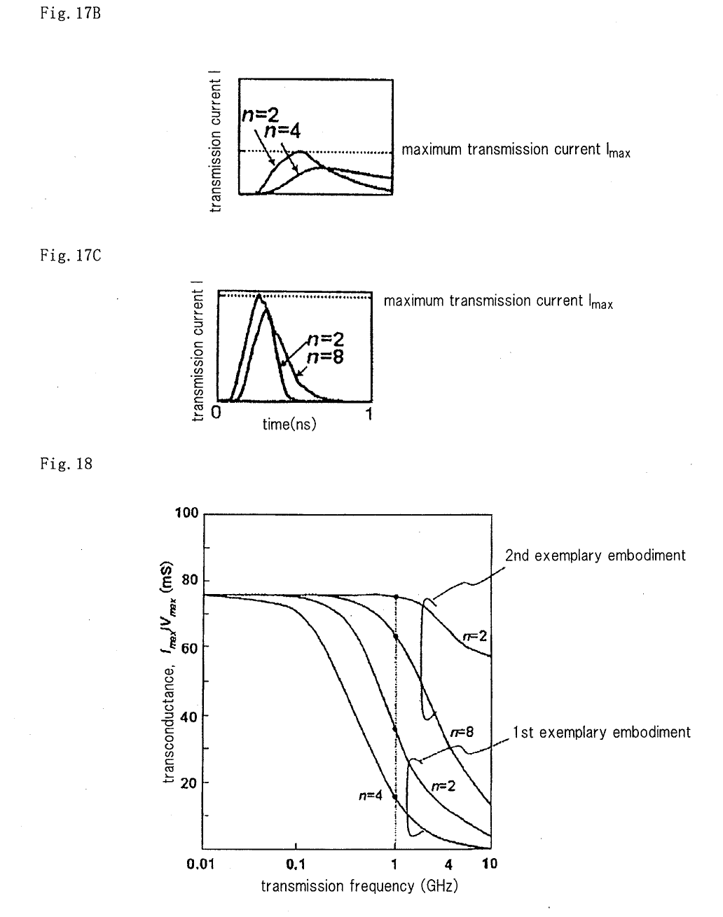

The results of characteristics of transmission currents according to the first and second exemplary embodiments will be describe below. FIGS. 17A through 17C are graphs showing transmission currents according to the first and second exemplary embodiment at a constant transmission voltage. FIG. 17A is a graph showing transmission voltages applied between the power supply and ground for data transmission. FIG. 17B is a graph showing transmission currents flowing through the transmission coils according to the first exemplary embodiment. FIG. 17C is a graph showing transmission currents flowing through the transmission coils according to the second exemplary embodiment.

According to the first exemplary embodiment, switch elements are inserted between a plurality of transmission coils that are connected together in a row. Therefore, the resistive and capacitive components of the switch elements are so influential that the transmission current is reduced if the number of transmission coils that are connected together in a row is increased. For example, if the number of transmission coils that are connected together in a row is increased from 2 to 4, then the maximum transmission current is reduced to about ½. When the transmission current is reduced, a voltage induced across the reception coil of the receiver is also reduced, tending to lower the S/N ratio. As a result, the semiconductor device becomes less resistant to noise and may possibly fail to transmit and receive data stably. Consequently, it is necessary to increase the reception current and employ greater transmission and reception coils for stable data transmission and reception.

According to the second exemplary embodiment, since no switch is present between a plurality of transmission coils that are connected together in a row, the amount of current flowing through the transmission coils is not greatly reduced even though the transmission coils are connected together in a row. For example, if eight coils are connected together in a row, the amount of current is reduced by about 10% or less compared with the amount of current flowing, through two coils that are connected together in a row. According to the second exemplary embodiment, therefore, it is possible to employ more transmission coils that are connected together in a row without the need for an increased transmission power and an increased coil shape than according to the first exemplary embodiment, so that the current can be reused with high efficiency.

The relationship between transconductance, which represents the ratio of a transmission current to a transmission voltage, and the transmission frequency according to the first and second exemplary embodiments will be described below.

FIG. 18 is a graph showing the relationship between the transconductance and the transmission frequency according to the first and second exemplary embodiments. The graph shows how the transmission current is reduced as the transmission frequency changes. According to the first exemplary embodiment, when two coils are connected together in a row, if the transmission frequency is 1 GHz, then the transconductance is reduced to one-half. It can be seen that when four coils are connected together in a row, the transconductance is reduced to one-quarter. According to the second exemplary embodiment, inasmuch as there is no switch element between a plurality of coils, the transconductance does not drop even though many coils are connected together in a row. It can be seen that when two coils are connected together in a row, the transconductance is essentially not reduced, and when eight coils are connected together in a row, the transconductance is reduced by only 15%. When the number of coils increases in the second exemplary embodiment, the transconductance is reduced because the parasitic resistive and capacitive components of the transmission coils and the parasitic resistive and capacitive components of the interconnects connecting the coils are increased.

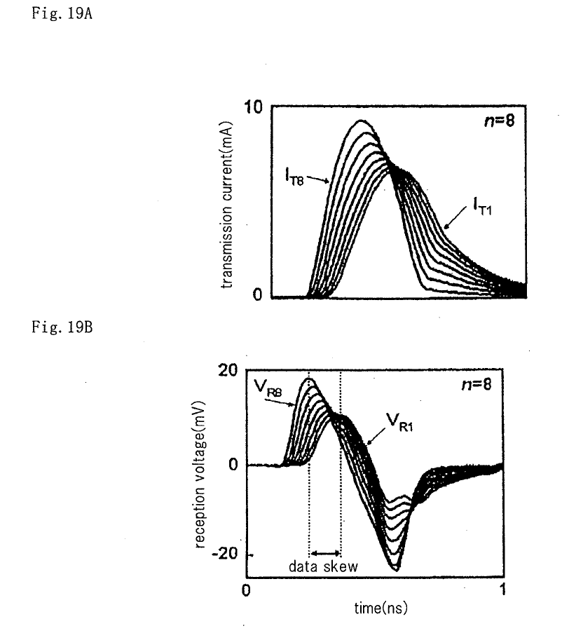

The results of characteristics of the transmission current and the reception voltage according to the second exemplary embodiment will be described below. FIG. 19A is a graph showing transmission currents flowing through respective eight transmission coils that are connected together in a row, and FIG. 19B is a graph showing reception voltages induced across the reception coils of eight receivers for receiving the data. The horizontal axis of each of the graphs represents time.

When all the eight data send polarity information 1, all the transmission coils can be connected together into one coil. FIG. 19A shows changes in the currents flowing through the transmission coils. The transmission current first starts flowing from the eighth transmission coil, and finally flows into the first transmission coil, whereupon the data transmission from all the transmission coils is finished. At this time, the transmission current is gradually reduced from the eighth coil to the first coil because of the resistive and capacitive components of the transmission coils and the resistive and capacitive components of the interconnects connecting the transmission coils, and simultaneously, the time during which the maximum transmission current flows is gradually shifted. As a consequence, the reception voltages induced across the reception coils are reduced, and the reception time is shifted. Deviations of the time for receiving the maximum reception voltages induced across the reception coils are referred to as a data skew.

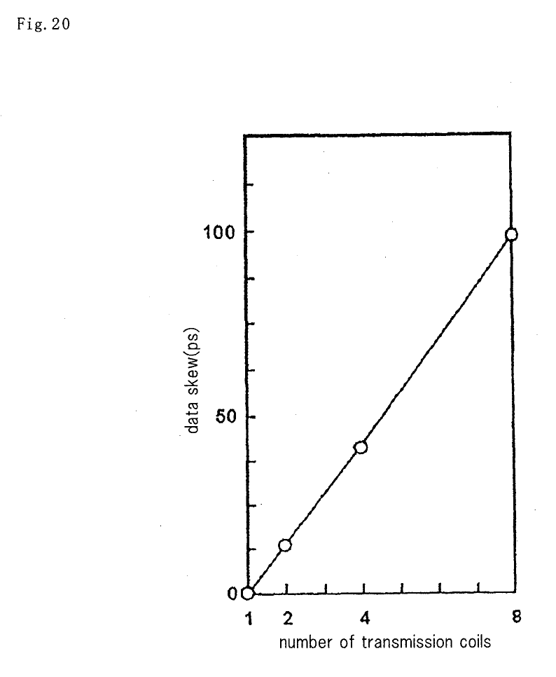

FIG. 20 is a graph showing the dependency of the data skew on the number of coils according to the second exemplary embodiment.

The data skew increases in proportion to the number of transmission coils that are connected together in a row According to the illustrated measured results, the data skew is of about 45 ps when four coils are connected together, and is of about 100 ps when eight coils are connected together. If the data skew is large, then it is difficult for the receiver to receive data accurately with a reception clock at one timing. Therefore, in view of the reduction in the transmission current as describe above and also the data skew, an infinitely large number of transmission coils cannot be connected together in a row. According to the second exemplary embodiment, it is considered appropriate to connect about eight transmission coils together in a row from the standpoints of the transmission power reducing effect and the limitation posed on the timing by the data skew.

As described above according to the first and second exemplary embodiments, the semiconductor device and the signal transmission method according to the present invention do not invite an increase in the transmission power which is proportional to the number of transmission bits, as observed when multibit data are transmitted according to the background art. The current consumed when multibit data are transmitted can be reduced, and the power consumption by the chips can be reduced.

The semiconductor device according to the present invention can also be used as a signal transmitter for data transmission.

The present invention is not limited to the above embodiments, but various changes may be made within the scope of the present invention and should be included in the scope of the present invention.

1-14. (canceled)

15. A semiconductor device comprising:
a plurality of semiconductor chips; and
at least one transmission coil for transmitting a first signal between said semiconductor chips using an inductive coupling;
wherein a plurality of said transmission coils are connected in series with each other.

16. The semiconductor device according to claim 15, wherein a plurality of said transmission coils are connected in series between a power supply for supplying a current to said transmission coils and ground.

17. The semiconductor device according to claim 15, further comprising a power supply or ground connected between adjacent ones of said transmission coils and shared by said adjacent ones of said transmission coils.

18. The semiconductor device according to claim 17, wherein a current flowing from the power supply between said adjacent ones of said transmission coils through said transmission coils, or a current flowing between said adjacent ones of said transmission coils to ground has opposite directions between said adjacent ones of said transmission coils.

19. The semiconductor device according to claim 15, further comprising switch elements for controlling said direction of a current flowing through said transmission coils.

20. The semiconductor device according to claim 19, wherein said switch elements are connected to opposite ends of said transmission coils.

21. The semiconductor device according to claim 15, wherein a second signal for determining a timing to cause a current to flow through said transmission coils for transmitting said first signal comprises a pulse signal having a pulse duration which is equal to or smaller than one-half of the period of a clock signal.

22. The semiconductor device according to claim 15, wherein a timing to cause a current to flow through said transmission coils for transmitting said first signal has a period corresponding to the period of a clock signal.

23. The semiconductor device according to claim 15, wherein a second signal for determining a timing to cause a current to flow through said transmission coils for transmitting said first signal comprises a clock signal.

24. The semiconductor device according to claim 15, wherein a second signal for determining a timing to cause a current to flow through said transmission coils for transmitting said first signal comprises a pulse signal having a variable pulse duration.

25. The semiconductor device according to claim 15, wherein magnetic fields generated by said transmission coils when a current flows through said transmission coils are directed differently depending on a polarity of said first signal.

26. A signal transmitter comprising a semiconductor device according to claim 15.

27. A method of transmitting a signal between a plurality of semiconductor chips using an inductive coupling produced by currents flowing through transmission coils, comprising:
connecting said transmission coils in series with each other; and
supplying a current for transmitting said signal from a power supply to flow through said transmission coils to ground.

28. The method according to claim 27, comprising:
providing a power supply or ground connected between adjacent ones of said transmission coils and shared by said adjacent ones of said trans-mission coils; and
transmitting data having different polarities from said adjacent ones of said transmission coils.
